(19) United States
(12) Patent Application Publication
(10) Pub. No.: US 2025/0353535 A1
(43) Pub. Date: Nov. 20, 2025

(54) CONVEYANCE SYSTEM, MAIN DOLLY, AND MAINTENANCE METHOD FOR SEMICONDUCTOR PRODUCTION APPARATUS

(71) Applicant: Kokusai Electric Corporation, Tokyo (JP)

(72) Inventors: Takeshi ITO, Toyama-shi (JP); Nobuhito TAKATA, Toyama-shi (JP)

(73) Assignee: Kokusai Electric Corporation, Tokyo (JP)

(21) Appl. No.: 19/283,553

(22) Filed: Jul. 29, 2025

Related U.S. Application Data
(63) Continuation of application No. PCT/JP2023/003389, filed on Feb. 2, 2023.

(51) Int. Cl. B62B 3/04; E01C 9/02; H01L 21/687

(52) U.S. Cl. CPC B62B 3/04; E01C 9/02; B62B 2202/90; B62B 2207/00; B62B 2301/044; B62B 2301/08; B62B 2301/12; B62B 2301/252; H01L 21/68707

(57) ABSTRACT

Provided is a technique including: a main dolly that includes a cargo platform, three or more wheels supporting the cargo platform, and a handle connected to the cargo platform; and a sub dolly that is configured to be movable between a position on the cargo platform of the main dolly and a position outside the cargo platform, wherein the sub dolly includes a front wheel and a rear wheel enabling the sub dolly to move at least in a forward and backward direction, a holder configured to hold an object so that its center of gravity ahead of the front wheel, and a counterweight detachably provided behind the front wheel, and the main dolly is configured to be capable of carrying and conveying the sub dolly in a state of holding the object.

### CROSS-REFERENCE TO RELATED APPLICATION

This application is a Bypass Continuation Application of PCT International Application No. PCT/JP2023/003389, filed on Feb. 2, 2023, the entire contents of which are incorporated herein by reference.

### BACKGROUND

### Field

The present disclosure relates to a conveyance system, main dolly, and Maintenance method for semiconductor production apparatus.

### Description of the Related Art

There has been disclosed a proposal of using a dolly including a lift in replacing a reaction tube of a substrate processing apparatus.

### SUMMARY

There is a case where an object installed in the substrate processing apparatus is replaced for maintenance. Here, the object is, for example, a transfer machine (transfer robot) for transferring a semiconductor substrate that is a heavy object.

The present disclosure provides a technique for replacing a heavy object installed in a substrate processing apparatus.

According to an aspect of the present disclosure, there is provided a technique including: a main dolly that includes a cargo platform, three or more wheels supporting the cargo platform, and a handle connected to the cargo platform; and a sub dolly that is configured to be movable between a position on the cargo platform of the main dolly and a position outside the cargo platform, wherein the sub dolly includes a front wheel and a rear wheel enabling the sub dolly to move at least in a forward and backward direction, a holder configured to hold an object so that its center of gravity is located ahead of the front wheel, and a counterweight detachably provided behind the front wheel, and the main dolly is configured to be capable of carrying and conveying the sub dolly in a state of holding the object.

### BRIEF DESCRIPTION OF THE DRAWINGS

FIG. 1 is a top view illustrating an example of a substrate processing apparatus according to an example of the present disclosure.

FIG. 2 is a longitudinal cross-sectional view illustrating an example of the substrate processing apparatus according to an example of the present disclosure.

FIG. 3 is a perspective view illustrating an example of a main dolly according to an example of the present disclosure.

FIG. 4 is a top view illustrating an example of a traveling path according to an example of the present disclosure.

FIG. 5 is a longitudinal cross-sectional view illustrating an example of the traveling path according to an example of the present disclosure.

FIG. 6 is a perspective view illustrating the traveling path and a sub dolly according to an example of the present disclosure.

FIG. 7 is a side view describing the sub dolly according to an example of the present disclosure.

FIG. 8 is a side view of the sub dolly to which a support jig is attached according to an example of the present disclosure.

FIG. 9 is a perspective view illustrating transfer of an object to a conveyance dolly according to an example of the present disclosure.

FIG. 10 is a view describing a maintenance method for a semiconductor production apparatus according to an example of the present disclosure.

### DETAILED DESCRIPTION

An aspect of the present disclosure will be described later with reference to the drawings. The drawings used in the following description are schematic, and a dimensional relationship between elements, a ratio between elements and the like illustrated in the drawings do not necessarily coincide with actual ones. In addition, dimensional relationships between elements, ratios between elements, and the like do not necessarily coincide with each other between a plurality of drawings.

In the present example, a substrate processing apparatus (also referred to as a semiconductor production apparatus) is configured as a vertical substrate processing apparatus (hereinafter, referred to as a substrate processing apparatus) 1 that performs a substrate processing step such as heat treatment as one step of a manufacturing step in a method for manufacturing a semiconductor device (device).

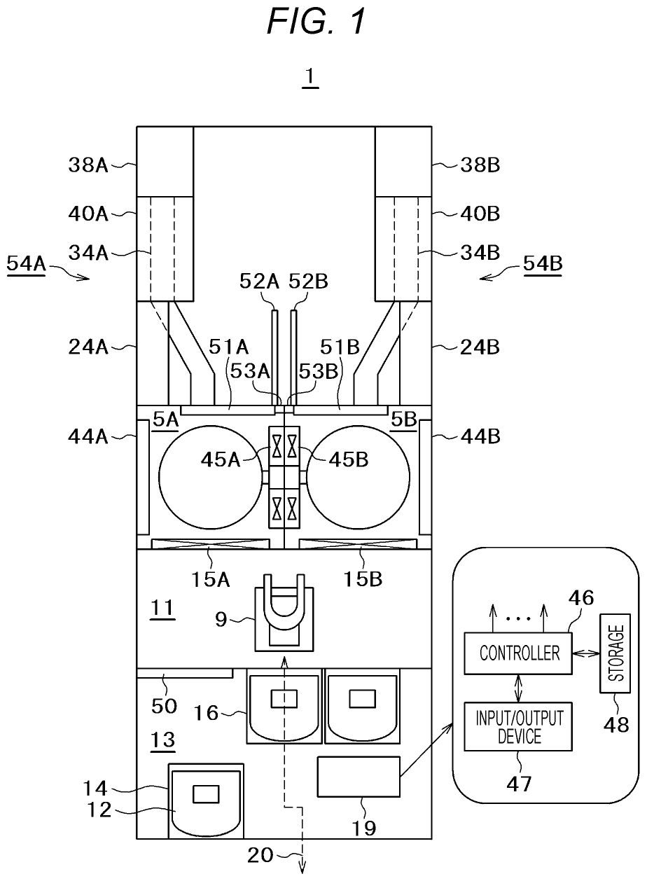

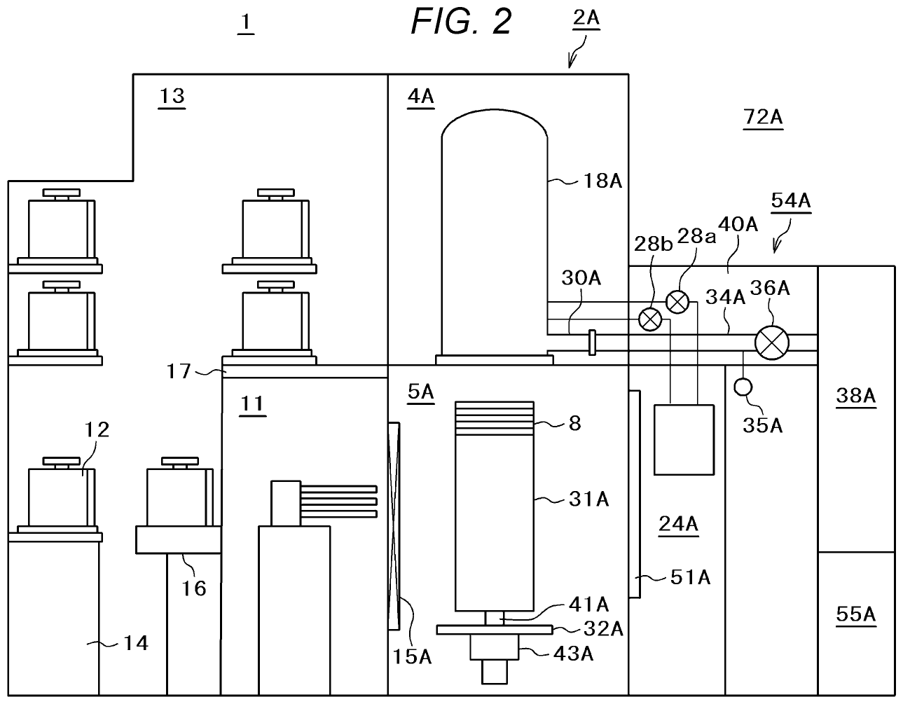

As illustrated in FIGS. 1 and 2, the substrate processing apparatus 1 includes a first processing module 2A and a second processing module 2B. The processing modules 2A and 2B each have a housing or a framework having a substantially rectangular parallelepiped outline, and one side surface of each is disposed in close contact with or adjacent to each other in parallel. The processing module 2A is configured by a first processing furnace 4A and a first transfer chamber 5A. The processing module 2B is configured by a second processing furnace 4B and a second transfer chamber 5B.

The transfer chambers 5A and the transfer chamber 5B are disposed below the processing furnace 4A and the processing furnace 4B, respectively. A transfer chamber 11 is disposed adjacent to a front surface side of the transfer chamber 5A and the transfer chamber 5B. The transfer chamber 11 can be called an equipment front end module (EFEM). The transfer chamber 11 has a housing having an approximately rectangular parallelepiped outer shape, and includes a transfer machine 9 serving as a substrate transfer robot for transferring a wafer 8. A storage chamber 13 that stores a pod (hoop) 12 that stores a plurality of wafers 8 is coupled to a front surface side of the transfer chamber 11. The storage chamber 13, the processing modules 2A and 2B, and the transfer chamber 11 have outer diameters based on polyhedrons formed of surfaces orthogonal to each other, and are configured to be detachable, and connection portions thereof have appropriate airtightness. An I/O port 14 is installed on a front surface of the storage chamber 13, and the pod 12 is carried in and out of the substrate processing apparatus 1 via the I/O port 14. In addition, the storage chamber 13 is provided with a load port 16 such as a front-opening interface mechanical standard (FIMS) connected to a front surface of the transfer chamber 11, and opens and closes the pod 12. The wafer 8 taken out from the pod 12 is handled in the transfer chamber 11 and the transfer chambers 5A and 5B constituting the mini-environment. The storage chamber 13 is provided with a maintenance port 50.

On a boundary wall (adjacent surface) between the transfer chambers 5A and 5B and the transfer chamber 11, a first gate valve 15A and a second gate valve 15B for carrying the wafer (substrate) 8 therebetween are installed. A pressure detector is installed in each of the transfer chamber 11 and the transfer chambers 5A and 5B, and the pressure in the transfer chamber 11 is set so as to be lower than the pressure in the transfer chambers 5A and 5B. In addition, an oxygen concentration detector is installed in each of the transfer chamber 11 and the transfer chambers 5A and 5B, and the oxygen concentration in the transfer chamber 11 and the transfer chambers 5A and 5B is maintained so as to be lower than the oxygen concentration in the atmosphere. A clean unit 17 that supplies clean air into the transfer chamber 11 is installed on a ceiling of the transfer chamber 11, and is configured to circulate, for example, an inert gas as clean air in the transfer chamber 11. By circulating and purging the inside of the transfer chamber 11 with an inert gas, the inside of the transfer chamber 11 can be made into a clean atmosphere. With such a configuration, it is possible to suppress particles and the like in the transfer chambers 5A and 5B from being mixed into the transfer chamber 11, and it is possible to suppress formation of a natural oxide film on the wafer 8 in the transfer chamber 11 and the transfer chambers 5A and 5B.

Since the processing module 2A and the processing module 2B have substantially the same (plane symmetric) configuration except for details, the first processing module (processing module 2A) will be representatively described later.

The processing furnace 4A includes a cylindrical first processing vessel 18A (reaction tube 18A) and a heater serving as a heating means (heating mechanism) installed around the reaction tube 18A. The reaction tube 18A is formed from, for example, quartz (Si) or silicon carbide (SiC). A first process chamber that processes the wafer 8 serving as a substrate is formed inside the reaction tube 18A. In addition, in the reaction tube 18A, a temperature detection portion serving as a temperature detector is erected along an inner wall of the reaction tube 18A.

A gas to be used for substrate processing is supplied into a process chamber 21A by a first gas supply mechanism serving as a gas supply system. The gas supplied by the gas supply mechanism is changed in accordance with a kind of a film to be formed. Here, the gas supply mechanism includes a source gas supplier, a reactant gas supplier, and an inert gas supplier. The gas supply mechanism is housed in a first supply box 24A (gas box) to be described later.

The source gas supplier includes a gas supply pipe, and the gas supply pipe is provided with a mass flow controller (MFC) serving as a flow rate controller and a valve serving as an opening/closing valve in order from an upstream direction. The gas supply pipe is connected to a nozzle penetrating a sidewall of a first manifold. The nozzle is erected in the reaction tube 18A along an up-down direction, and includes a plurality of supply holes opened toward the wafer 8 held by a first boat 31A. A source gas is supplied to the wafer 8 through the supply holes of the nozzle.

Hereinafter, with a similar configuration, a reactant gas is supplied from the reactant gas supplier to the wafer 8 via the gas supply pipe, the MFC, a valve 28b, and the nozzle. An inert gas is supplied from the inert gas supplier to the wafer 8 via the gas supply pipe, the MFC, the valve, and the nozzle.

A lower end opening of the reaction tube 18A is disposed corresponding to a ceiling of the transfer chamber 5A, and is opened and closed by a disk-shaped first lid 32A (lid 32A). A seal member such as an O-ring is installed on an upper surface of the lid 32A, whereby the reaction tube 18A is hermetically sealed from the outside air. A first heat insulator 33A (heat insulator 33A) is placed on the lid 32A. A cylindrical manifold can be provided between the reaction tube 18A and the lid 32A.

A first exhaust port 30A extending outward is formed in the reaction tube 18A or the manifold, and a first exhaust pipe 34A is attached via the exhaust port 30A. The exhaust pipe 34A is connected to a first booster pump 38A serving as a vacuum-exhaust device via a first pressure sensor 35A (pressure sensor 35A) serving as a pressure detector (pressure detection portion) that detects the pressure in the process chamber and a first conductance variable valve 36A serving as a pressure regulator (pressure regulation portion). With such a configuration, the pressure inside the process chamber 21A can be set to a processing pressure in accordance with processing. The exhaust pipe 34A, the pressure sensor 35A, and the conductance variable valve 36A mainly constitute an exhaust system 39A as a first exhaust system. The exhaust system 39A can be housed in a first exhaust box 40A (exhaust box 40A) described later.

The process chamber of the reaction tube 18A houses the boat 31A serving as a substrate holder for vertically supporting a plurality of, for example, 10 to 150, wafers 8 in a shelf shape. The boat 31A is supported above the heat insulator by a first rotation shaft 41A (rotation shaft 41A) that penetrates the lid 32A and the heat insulator. The rotation shaft 41A is connected to a first rotation mechanism installed below the lid 32A, and the rotation shaft 41A is configured to be rotatable in a state of hermetically sealing the inside of the reaction tube 18A. The lid 32A is driven in the up-down direction by a first boat elevator 43A (boat elevator 43A) serving as a lifting mechanism. As a result, the boat 31A and the lid 32A are integrally raised or lowered, and the boat 31A is loaded to and unloaded from the reaction tube 18A.

The transfer of the wafer 8 to the boat 31A is performed in the transfer chamber 5A. As illustrated in FIG. 1, a first clean unit 44A (clean unit 44A) is installed on one side surface (outer side surface of the transfer chamber 5A, side surface opposite to side surface facing the transfer chamber 5B) of the transfer chamber 5A, and is configured to circulate clean air (for example, inert gas) in the transfer chamber 5A. The inert gas supplied into the transfer chamber 5A is exhausted from the transfer chamber 5A by a first exhauster 45A (exhauster 45A) installed on a side surface facing the clean unit 44A across the boat 31A (side surface facing the transfer chamber 5B), and is re-supplied from the clean unit 44A into the transfer chamber 5A (circulation purge). The pressure in the transfer chamber 5A is set to be always lower than the pressure in the transfer chamber 11. This prevents particles and contamination sources in the transfer chamber 5A from being brought into the transfer chamber 11 to spread the contamination. In addition, the oxygen concentration in the transfer chamber 5A is set to be lower than the oxygen concentration in the atmosphere.

A controller 46 serving as a control portion for controlling the rotation mechanism, the boat elevator 43A, the MFC of the gas supply mechanism, valves 28a to 28b, and the conductance variable valve 36A is connected thereto. As illustrated in FIG. 1, the controller 46 is housed in a control box 19 provided in the storage chamber 13 of the substrate processing apparatus 1. The controller 46 includes, for example, a microprocessor (computer) including a CPU, and is configured to control the operation of the processing modules 2A and 2B. The controller 46 is connected to an input/output device 47 configured as, for example, a touch panel or the like. One controller 46 may be installed in each of the processing module 2A and the processing module 2B, or one common controller 46 may be installed.

A storage 48 serving as a storage medium is connected to the controller 46. The storage 48 readably stores a control program to control the operation of the substrate processing apparatus 1 and a program (also referred to as a recipe) for causing each of the constituent elements of the substrate processing apparatus 1 to execute processing in accordance with processing conditions.

The storage 48 may be a storage device (hard disk or flash memory) incorporated in the controller 46, or may be a portable external memory (a magnetic tape, a magnetic disk such as a flexible disk or a hard disk, an optical disk such as a CD or a DVD, a magneto-optical disk such as an MO, or a semiconductor memory such as a USB memory or a memory card). In addition, a program may be provided to the computer by using a communication means such as the Internet or a dedicated line. The program is read from the storage by an instruction or the like from the input/output device 47 as needed, and the controller 46 executes processing according to a read recipe, so that the substrate processing apparatus 1 executes desired processing under the control of the controller.

Next, a back surface configuration of the substrate processing apparatus 1 will be described.

As illustrated in FIG. 1, a first maintenance port 51A and a second maintenance port 51B are formed on the back surface side of the transfer chambers 5A and 5B, respectively. The maintenance ports 51A and 51B are opened and closed by a first maintenance door 52A and a second maintenance door 52B. Further, a maintenance area for performing maintenance of the transfer chamber, the processing furnace, and the like is continuously formed on the processing module 2B side on the back surface of the processing module 2A and on the processing module 2A side on the back surface of the processing module 2B.

A first utility system 54A (utility system 54A) and a second utility system 54B (utility system 54B) extending rearward are installed close to the back surfaces of the processing modules 2A and 2B. The utility systems 54A and 54B are disposed symmetrically with respect to each other with the maintenance area interposed therebetween. The utility systems 54A and 54B include supply boxes 24A and 24B, exhaust boxes 40A and 40B, and booster pumps 38A and 38B. The maintenance ports of the boxes of the utility systems 54A and 54B are formed on the inner side (maintenance area side).

Since the utility systems 54A and 54B have substantially the same configuration except for details, the utility system 54A will be described later as a representative. The supply box 24A is disposed adjacent to an outer portion of the back surface of the transfer chamber 5A. The exhaust box 40A is disposed adjacent to an outer portion of the back surface of the processing furnace 4A. That is, the outer side surfaces of the supply box 24A and the exhaust box 40A are positioned flatly (smoothly) so as to be connected to the outer side surface of the transfer chamber 5A substantially continuously. In addition, the supply box 24A and the exhaust box 40A are adjacent to each other in the up-down direction. The back surfaces of the supply box 24A and the exhaust box 40A are substantially flush.

The booster pump 38A is disposed adjacent to the back surfaces of the supply box 24A and the exhaust box 40A. The booster pump 38A is housed in a housing (frame body) having a substantially rectangular parallelepiped outline, and can be installed on a first frame 55A (frame 55A) having a predetermined height.

The booster pumps 38A and 38B have outer side surfaces disposed so as not to protrude outward from the outer side surfaces of the utility systems 54A and 54B, that is, the outer side surfaces of the exhaust boxes 40A and 40B and the outer side surfaces of the supply boxes 24A and 24B.

Next, a maintenance method for maintaining the semiconductor production apparatus (substrate processing apparatus) by replacing the transfer machine 9 installed in the transfer chamber 11, and a conveyance system for replacing the transfer machine 9 installed in the transfer chamber 11 will be described. The transfer machine 9 in the present example is installed in a central portion of the substrate processing apparatus 1 away from any of the front surface, the back surface, and the left and right side surfaces of the substrate processing apparatus 1. In order to replace the transfer machine 9, referring to FIG. 1, first, the load port 16 (here, at least one in front of the transfer machine 9 among the two load ports) provided on the back surface side of the storage chamber 13 and the control box 19 provided on the front surface side of the load port 16 are removed and taken out to the outside of the substrate processing apparatus 1. A traveling path 20 schematically indicated by the dotted line is installed inside the storage chamber 13. Next, the transfer machine 9 that needs to be replaced is taken out from the transfer chamber 11 to the outside of the semiconductor production apparatus 1 corresponding to substantially the center on the front surface side of the substrate processing apparatus 1 via the storage chamber 13 along the traveling path 20. Thereafter, a new transfer machine 9 is carried from the outside of the substrate processing apparatus 1 to the transfer chamber 11 via the storage chamber 13 along the traveling path 20 with respect to substantially the center on the front surface side of the substrate processing apparatus 1, and is attached in the transfer chamber 11. In this example, the traveling path 20 includes a crank (left reverse turn). This is to avoid interference with equipment such as other components (for example, I/O port 14) installed in the storage chamber 13. In a case where there is no interfering equipment, the traveling path 20 may be linear.

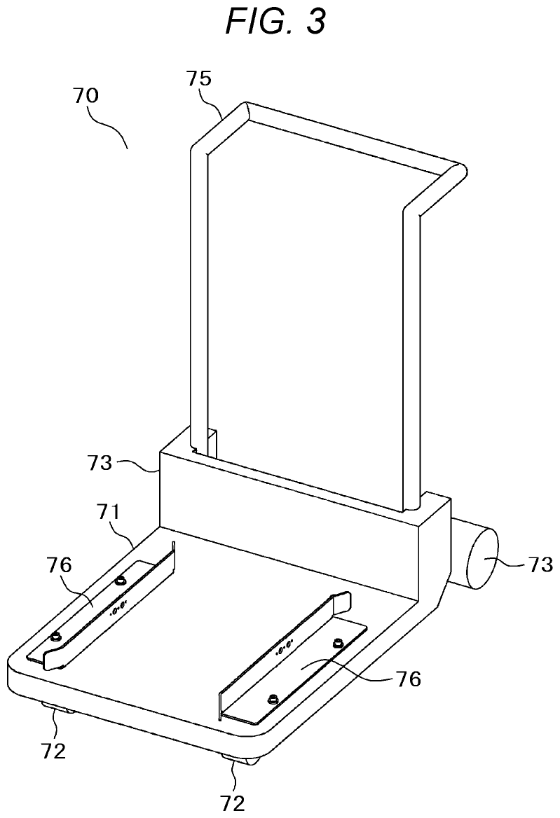

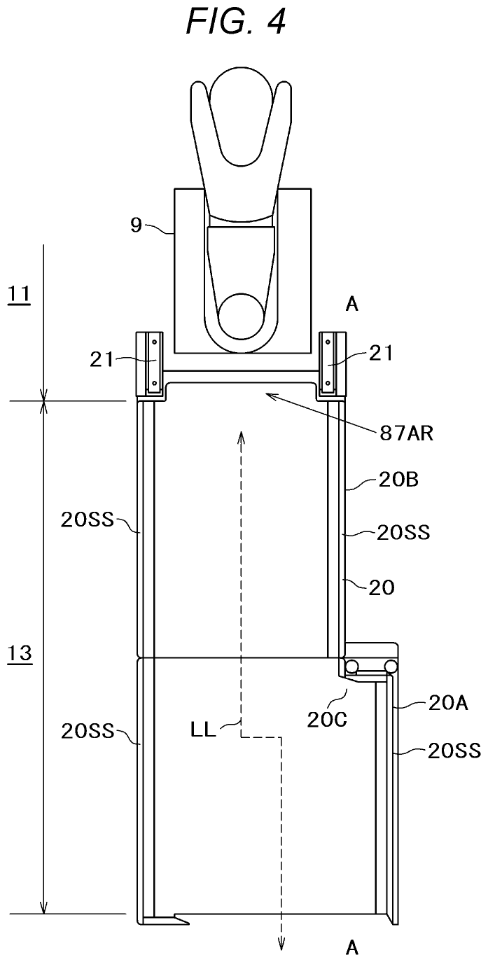

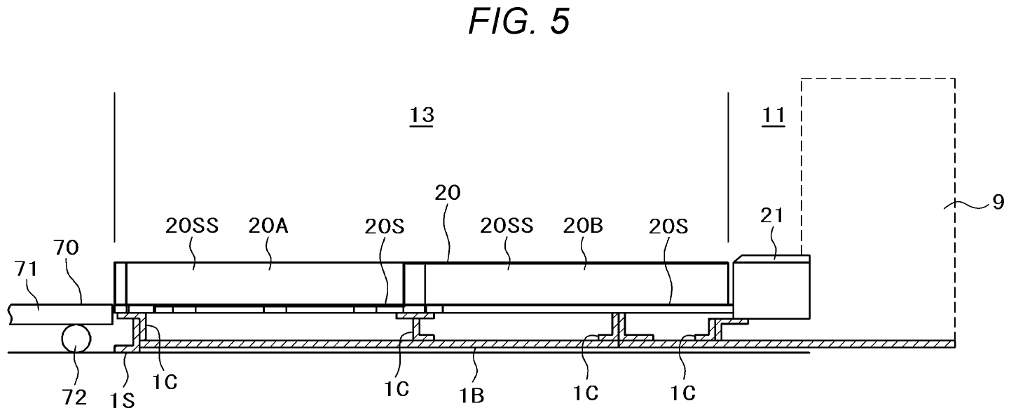

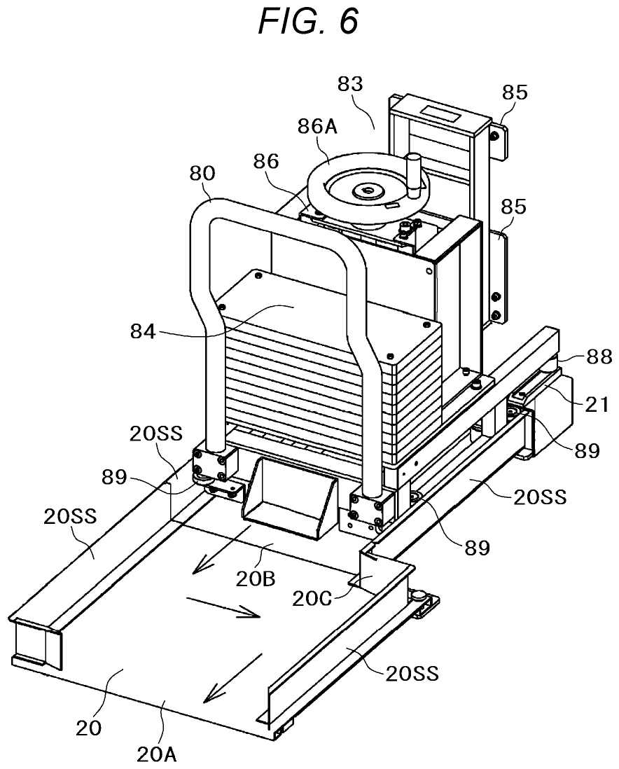

A conveyance system is used to convey the heavy transfer machine 9 along the traveling path 20. Hereinafter, the conveyance system will be described with reference to the drawings. The conveyance system is configured by a main dolly 70 illustrated in FIG. 3 and a sub dolly 80 illustrated in FIG. 6. In the traveling path 20 illustrated in FIGS. 4 and 5, the sub dolly 80 configured to be movable in front-rear and left-right directions travels.

As illustrated in FIG. 3, the main dolly 70 includes a cargo platform 71, three or more wheels 72 and 73 supporting the cargo platform 71, a handle 75 connected to the cargo platform 71, and a pair of fixers 76 for guiding and fixing the sub dolly 80 to a predetermined position on the cargo platform 71. The main dolly 70 is configured to be able to convey the sub dolly 80 in a state of holding the transfer machine 9, which is an object to be conveyed. In the present disclosure, the side on which the sub dolly 80 is loaded and unloaded is defined as the front side of the main dolly. The wheels 72 are two front wheels and the wheels 73 are two rear wheels, which enable the main dolly to move at least back and forth. As the wheel 72, a swivel caster having a barrel-shaped tire can be used. It is desirable that the wheels 72 and 73 have a width larger than the width of a grating so as to enable stable traveling on the floor of the grating. In FIG. 3, the rear wheels 73 are schematically drawn. The pair of fixers 76 has side walls abutting on guide rollers 89 of the sub dolly 80 described later and holes for fixing the sub dolly 80 with bolts or the like. The object to be conveyed is not limited to the transfer machine 9, and may be one or more objects mounted inside the substrate processing apparatus 1.

FIG. 4 illustrates a plan view of the traveling path 20 provided in the substrate processing apparatus 1. The traveling path 20 is detachably provided in the storage chamber 13 of the substrate processing apparatus 1. FIG. 4 schematically illustrates a state in which the transfer machine 9 is attached in the transfer chamber 11. As illustrated in FIG. 4, the traveling path 20 includes a first traveling path 20A and a second traveling path 20B. The first traveling path 20A is installed on the front side of the storage chamber 13, and the second traveling path 20B is installed on the rear side of the storage chamber 13 so as to be continuous with the first traveling path 20A. That is, the second traveling path 20B is installed between the first traveling path 20A and the transfer chamber 11. As a result, the traveling path 20 is provided so as to start from the side of the substrate processing apparatus 1 where the processing furnace 4A is not provided, and is configured such that the object can be carried in and out from the front side of the substrate processing apparatus 1. In addition, there are two corners that are bent at right angles as indicated by an imaginary line LL indicating the traveling direction of the passage, and therefore, the traveling path 20 includes a crank 20C and is provided outside the EFEM serving as the transfer chamber 11.

Auxiliary rails 21 can be provided inside the transfer chamber 11. As illustrated in FIG. 5, the auxiliary rails 21 are configured such that a pair of auxiliary front wheels 88 provided on the sub dolly 80 can travel on the auxiliary rails 21 provided inside the transfer chamber 11 when the sub dolly 80 is at the loading/unloading position of the object and a predetermined section immediately before the loading/unloading position of the object.

The auxiliary front wheels 88 and the auxiliary rails 21 are for further improving safety, and are not indispensable. Safety can also be maintained by increasing a counterweight 84 described later without using the auxiliary front wheels 88 or the like. The auxiliary rails 21 are conceptually included in the traveling path.

FIG. 5 illustrates a longitudinal cross-sectional view taken along line AA of the traveling path 20 illustrated in FIG. 4. As illustrated in FIG. 5, the bottom of the substrate processing apparatus 1 has a framework structure firmly configured by a bottom plate 1B and reinforcing members (beams) 1C such as T-shaped steel, Z-shaped steel, or I-shaped steel that reinforce the bottom plate 1B on the upper surface of the bottom plate 1B, and is fixed to the floor by a stay 1S connected to the reinforcing members 1C. The transfer machine 9, the load port 16, and the like are appropriately installed on the bottom plate 1B using a pedestal or the like. Each of the traveling paths 20A and 20B includes a flat traveling surface (surface) 20S, sidewalls 20SS standing upright on both sides in the traveling direction of the traveling surface 20S, and a reinforcing member 20R such as a hat-shaped or lip groove-shaped steel that reinforces the traveling surface on the back side of the traveling surface 20S. The traveling paths 20A and 20B are placed and fixed on the upper ends of the reinforcing members 1C, and the sidewalls 20SS standing upright on both sides in the traveling direction of the passage, the surface 20S of the traveling path 20 (20A, 20B) at that time, and the upper surface of the cargo platform 71 of the main dolly 70 are set to substantially the same height. As a result, the sub dolly 80 installed on the upper surface of the cargo platform 71 can be easily moved to the surface 20S of the traveling path 20. The upper ends of the reinforcing members 1C are set to the same height, so that the sub dolly 80 can be horizontally moved on the traveling path 20. In addition, the transfer machine 9, which is an object held by the sub dolly 80, can be relatively easily installed on the surface on which the transfer chamber 11 is installed.

In addition, as illustrated in FIGS. 5 and 6, guide rollers 89 provided on both sides of the sub dolly 80 travel along the sidewalls 20SS provided on both sides of the traveling path 20, whereby the sidewalls 20SS prevent the sub dolly 80 from deviating from the traveling path 20. Since the traveling path 20 has a role of guiding the traveling of the sub dolly 80, it can also be referred to as a traveling guide. Two guide rollers 89 are provided on each side of the sub dolly 80 at a height at which they can come into contact with the sidewall 20SS of the traveling path 20. That is, two guide rollers 89 are provided on the right side of the sub dolly 80 and two guide rollers 89 are provided on the left side of the sub dolly 80. The guide roller 89 has a rotation shaft in a substantially vertical direction, and is configured to be rotatable in contact with the sidewall 20SS of the traveling path 20. The traveling path 20 may be provided separately on the left and right sides of the passage.

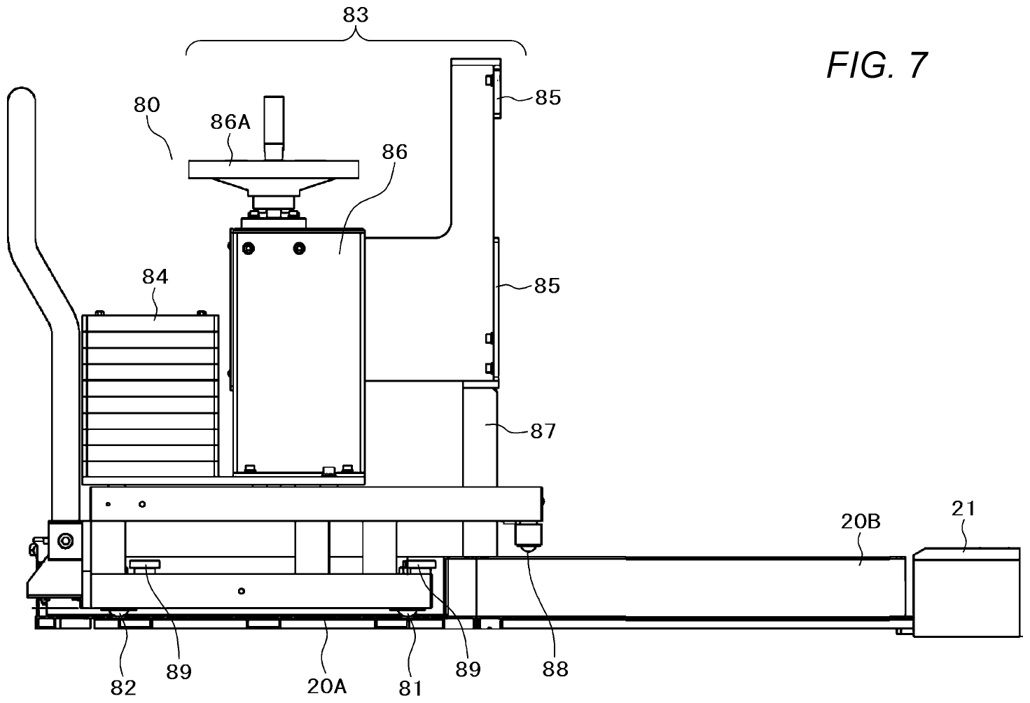

As illustrated in FIGS. 6 and 7, the sub dolly 80 includes front wheels 81 and rear wheels 82 that enable movement at least in the forward and backward direction, a holder 83 that holds an object 9 having a center of gravity ahead of the front wheels 81, and the counterweight 84 detachably provided behind the front wheels 81. The sub dolly 80 is configured independently of the main dolly 70, and is configured to be movable between the position on the cargo platform 71 of the main dolly 70 and the position outside the cargo platform 71. The counterweight 84 enables prevention of falling and safe working without fixing the sub dolly 80 to the body of the substrate processing apparatus 1 (even during traveling in the substrate processing apparatus 1). In addition, the counterweight 84 can be attached and detached, and is easy to handle when the sub dolly 80 is brought into a factory where the substrate processing apparatus 1 is installed. In addition, as illustrated in FIG. 5, since the sub dolly 80 horizontally moves, the safety is higher than the case of using a slope.

One front wheel 81 and one rear wheel 82 are provided on each of the left and right sides of the sub dolly 80 in the direction along the traveling direction of the passage. That is, the sub dolly 80 is provided with two front wheels 81 and two rear wheels 82. The corresponding front wheel 81 and rear wheel 82 are configured to travel on the same traveling path 20. At least one of the front wheel 81 and the rear wheel 82 of the sub dolly 80 is configured by a metal ball caster that can be used in a clean room. As a result, the sub dolly 80 is configured to be movable in the front-rear direction on the traveling path 20 and is also configured to be movable in the left-right direction. The front wheels 81 and the rear wheels 82 of the sub dolly 80, the two front wheels 81 of the sub dolly 80, or the two rear wheels 82 of the sub dolly 80 may be configured by metal ball casters. The ball caster is a wheel that rotates in an arbitrary direction, and at least one of the front wheel 81 and the rear wheel 82 of the sub dolly 80 is a metal ball caster, so that the sub dolly 80 can travel to a place that is difficult to access by straight traveling. As a result, the object 9 can be conveyed to a place that is difficult to access by straight traveling.

The pair of auxiliary front wheels 88 of the sub dolly 80 is provided ahead of the front wheels 81. The auxiliary front wheels 88 are configured to travel on the auxiliary rails 21 provided inside the transfer chamber 11 and to bear a part of the load of the object 9 instead of the front wheels 81 when the sub dolly 80 is at the loading/unloading position of the object 9 and a predetermined section immediately before the loading/unloading position of the object 9. In this manner, it is possible to minimize the entry of the sub dolly 80 into the transfer chamber 11 constituting the mini-environment and to prevent contamination in the mini-environment due to maintenance work.

The holder 83 of the sub dolly 80 includes a plate-shaped engager 85 that can be fixed to a side surface of the object 9 directly or with a bolt via a jig, and a lifting mechanism 86 that raises or lowers the engager 85. The lifting mechanism 86 includes a handle 86A, and can move the engager 85 upward by rotating the handle 86A, for example, in the right direction, and can move the engager 85 downward by rotating the handle 86A, for example, in the left direction.

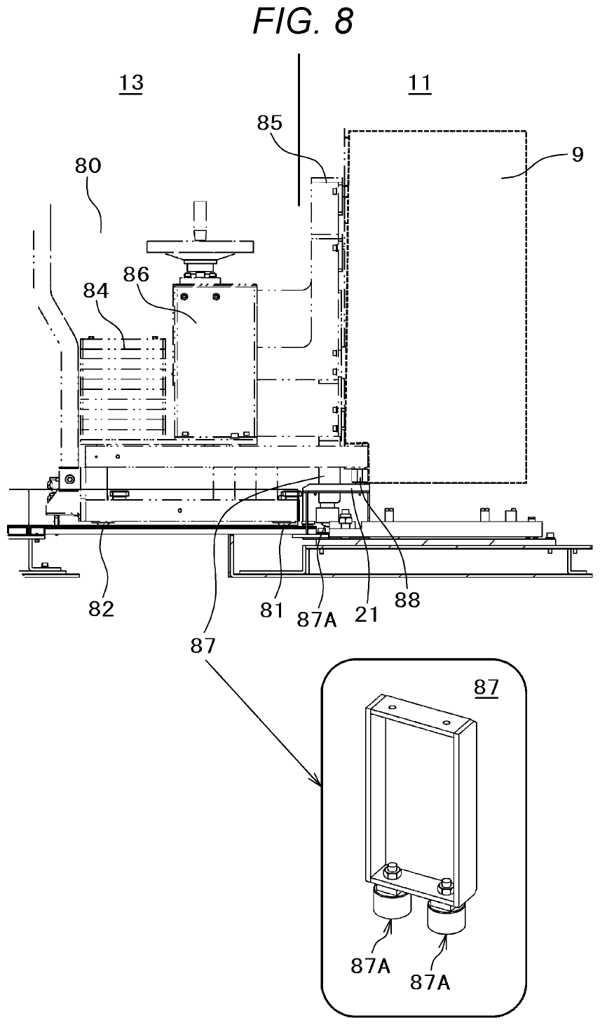

FIG. 8 depicts a side view of the sub dolly 80 to which a support jig 87 is attached and in which the object 9 is engaged with the engager. In addition, the sub dolly 80 of FIG. 8 is in a state of the loading/unloading position of the object 9, and travels on the traveling path 20 until approaching the loading/unloading position of the object 9. As illustrated in FIG. 8, the holder 83 can further include the support jig 87. The support jig 87 is fixed to a lower side of the holder 83 so as to be positioned between the front wheel 81 and the auxiliary front wheel 88 of the sub dolly 80. The support jig 87 include wheels 87A. The support jig 87 is joined to the engager 85, and is configured to be grounded to the traveling path 20 via the wheels 87A of the support jig 87 in a state of being at a height capable of engaging the object 9 on which the engager 85 is installed. A region grounded to the traveling path 20 via the wheels 87A of the support jig 87 is a portion of a region 87AR illustrated in FIG. 3, and is a side of the front side of the auxiliary rails 21. The support jig 87 is configured to be able to directly transmit at least a part of the load of the object 9 to the traveling path 20 by the wheels 87A. As described above, the configuration in which the object 9 is supported by the holder 83 of the sub dolly 80 is a configuration in which, as compared with the case of supporting with an arm, there is no reaction or vibration due to the bending of the arm and the risk of collision or the like with the substrate processing apparatus 1 is low.

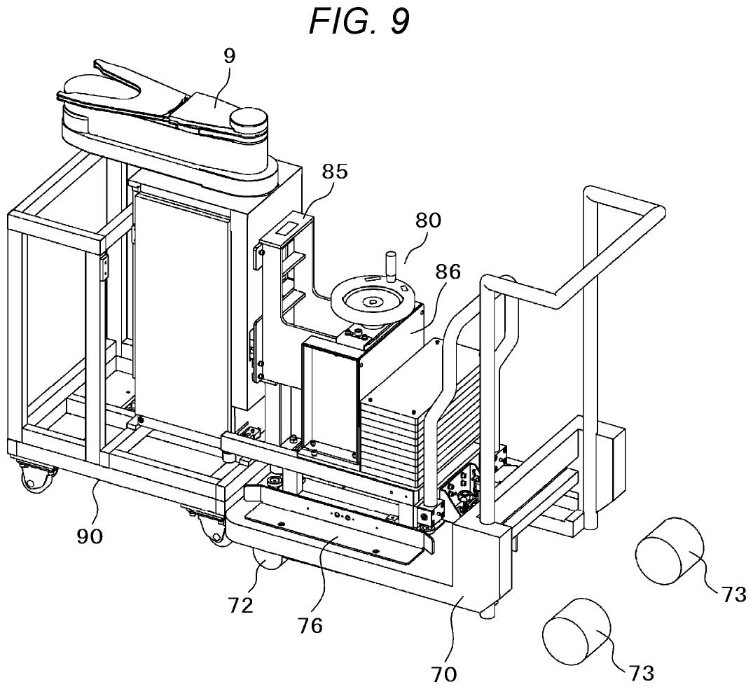

FIG. 9 illustrates the transfer of the object 9 to a conveyance dolly 90. The sub dolly 80 is in a state of being fixed to the fixers 76 of the main dolly 70, and the object 9 is attached to the engager 85 of the sub dolly 80. The engager 85 is raised by the lifting mechanism 86, and fixes the conveyance dolly 90 and the main dolly 70 by positioning a loader of the object 9 of the conveyance dolly 90 below the object 9. By lowering the engager 85 with the lifting mechanism 86, the object 9 is placed on the loader of the object 9 of the conveyance dolly 90, and the object 9 is fixed to the loader. Thereafter, the object 9 is removed from the engager 85, the conveyance dolly 90 and the main dolly 70 are unfixed, so that the conveyance dolly 90 and the main dolly 70 are movable, and the object 9 is moved with the conveyance dolly 90. When the object 9 is transferred from the conveyance dolly 90 to the sub dolly 80, it is possible to perform the above in the reverse order, and thus the description thereof will be omitted. As described above, the conveyance of the object 9 using the conveyance dolly 90 is easy to handle because the conveyance dolly 90 is light and small as compared with the case where the object 9 is conveyed with the main dolly 70 (and the sub dolly 80) (without transfer).

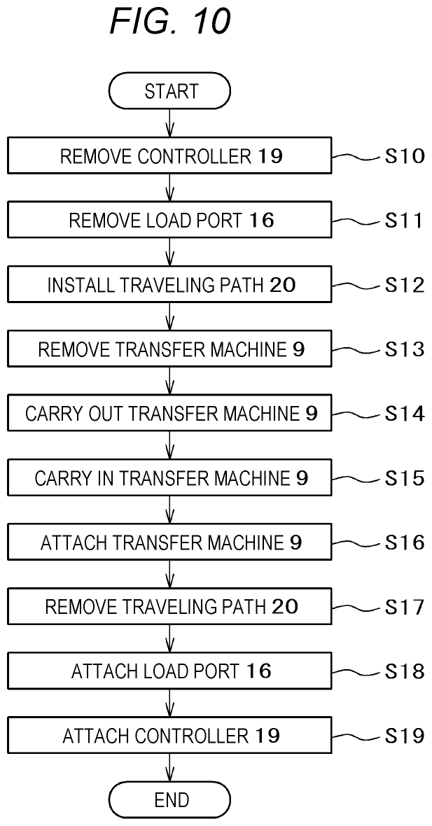

Next, a maintenance method of the semiconductor production apparatus 1 will be described with reference to FIG. 10. In this maintenance method, a configuration in which the transfer machine 9 serving as an object is first removed from the transfer chamber 11 and then a new transfer machine 9 is attached to the transfer chamber 11 will be described. Since the procedure of attaching the new transfer machine 9 to the transfer chamber 11 is equivalent to the reverse procedure of removing the transfer machine 9 from the transfer chamber 11, detailed description thereof may be omitted.

### (Step S10: Step of Removing Controller 19)

The control box 19 installed in the storage chamber 13 of the substrate processing apparatus 1 is removed, and the removed control box 19 is carried out to the outside of the substrate processing apparatus 1.

### (Step S11: Step of Removing Load Port 16)

The load port 16 installed in the storage chamber 13 is removed, and the removed load port 16 is carried out to the outside of the substrate processing apparatus 1. Then, it is needed to open a wall portion on the front surface side of the transfer chamber 11 so that the transfer machine 9 can be accessed.

### (Step S12: Step of Installing Traveling Path 20)

The traveling path 20 (20A, 20B) is installed in the storage chamber 13 (see FIG. 4).

### (Step S13: Step of Removing Transfer Machine 9)

The bolts of the transfer machine 9 fixed to the floor of the transfer chamber 11 with the bolts or the like are removed to make the transfer machine 9 removable from the floor of the transfer chamber 11. Next, the cargo platform 71 of the main dolly 70 on which the sub dolly 80 is mounted is connected to the traveling path 20. The main dolly 70 and the sub dolly 80 are unfixed to make the sub dolly 80 travelable. Since the surface of the traveling path 20 and the upper surface of the cargo platform 71 of the main dolly 70 are substantially at the same height (see FIG. 5), the sub dolly 80 can be relatively easily moved from the cargo platform 71 of the main dolly 70 to the traveling path 20. Then, the sub dolly 80 is caused to travel in the direction of the transfer chamber 11 along the traveling path 20. The sub dolly 80 travels on the traveling path 20 until approaching the loading/unloading position of the transfer machine 9. When the sub dolly 80 is at the loading/unloading position of the transfer machine 9 and a predetermined section immediately before the loading/unloading position of the transfer machine 9, the pair of auxiliary front wheels 88 of the sub dolly 80 travels on the auxiliary rails 21 provided in the EFEM (transfer chamber 11).

Next, the holder 83 of the sub dolly 80 is lowered. In this state, the engager 85 is in a state of being at a height capable of engaging the object 9 and is configured to be grounded to the traveling path 20 via the wheels 87A of the support jig 87. Next, the transfer machine 9 is engaged (fixed) with the engager 85 with a bolt or the like. Thereafter, the holder 83 is raised to bring the transfer machine 9 into a conveyable state.

At this time, because of the presence of the counterweight 84, the sub dolly 80 is in a stable posture even in a state where the transfer machine 9 is engaged. That is, the counterweight 84 is configured to enable prevention of falling and safe working without fixing the sub dolly 80 to the body of the substrate processing apparatus 1 (even during traveling on the traveling path 20 in the substrate processing apparatus 1).

### (Step S14: Step of Carrying Out Transfer Machine 9)

Next, the sub dolly 80 on which the transfer machine 9 is mounted is caused to travel on the traveling path 20 to move to the upper surface of the cargo platform 71 of the main dolly 70. Then, the sub dolly 80 is fixed to the cargo platform 71 of the main dolly 70 and moved to the conveyance dolly 90. As described with reference to FIG. 9, by lowering the engager 85, the transfer machine 9 is placed on the loader of the transfer machine 9 of the conveyance dolly 90, and the transfer machine 9 is fixed to the loader. The transfer machine 9 is removed from the engager 85, and the transfer machine 9 is conveyed with the conveyance dolly 90. That is, a step of directly transferring the transfer machine 9 between the sub dolly 80 mounted on the main dolly 70 and the conveyance dolly 90, and a step of conveying the transfer machine 9 with the conveyance dolly 90 after the transfer are performed.

### (Step S15: Step of Carrying In Transfer Machine 9)

In Step S15, a new transfer machine 9, which is a replacement object, is carried in by the reverse procedure of Step S14. That is, before the transfer, a step of conveying a new transfer machine 9 with the conveyance dolly 90 and a step of directly transferring the new transfer machine 9 between the sub dolly 80 mounted on the main dolly 70 and the conveyance dolly 90 are performed.

### (Step S16: Step of Attaching Transfer Machine 9)

In Step S16, a new transfer machine 9 is attached by the reverse procedure of Step S13.

### (Step S17: Step of Removing Traveling Path 20)

The traveling path 20 (20A, 20B) is removed from the storage chamber 13.

### (Step S18: Step of Attaching Load Port 16)

The removed load port 16 is carried into the substrate processing apparatus 1. The load port 16 is attached to the storage chamber 13.

### (Step S19: Step of Attaching Load Port 16)

The removed controller 19 is carried into the substrate processing apparatus 1. The controller 19 is attached to the storage chamber 13. Thus, the maintenance of the semiconductor production apparatus 1 is completed.

The present disclosure is not limited to the embodiments described above, and further includes various modified examples. For example, the above-described embodiments have been described in detail in order to describe the present disclosure in an easy-to-understand manner, and are not necessarily limited to those including the described configurations.

According to the present disclosure, it is possible to provide a technique for replacing a heavy object installed in a substrate processing apparatus.

What is claimed is:

1. A conveyance system comprising:
a main dolly that includes a cargo platform, three or more wheels supporting the cargo platform, and a handle connected to the cargo platform; and
a sub dolly that is configured to be movable between a position on the cargo platform of the main dolly and a position outside the cargo platform,
wherein the sub dolly includes:
a front wheel and a rear wheel enabling the sub dolly to move at least in a forward and backward direction,
a holder configured to hold an object so that its center of gravity is located ahead of the front wheel, and
a counterweight detachably provided behind the front wheel, and
wherein the main dolly is configured to be capable of carrying and conveying the sub dolly in a state of holding the object.

2. The conveyance system according to claim 1, wherein
the object is mounted in a substrate processing apparatus, and
the conveyance system further comprises:
a traveling path that is detachably provided in the substrate processing apparatus and enables the sub dolly to move to a loading/unloading position of the object.

3. The conveyance system according to claim 2, wherein
an upper surface of a framework structure at a bottom of the substrate processing apparatus, a surface of the traveling path, and an upper surface of the cargo platform of the main dolly are set at substantially a same height.

4. The conveyance system according to claim 2, wherein
one front wheel and one rear wheel are provided on each of left and right sides, and corresponding front wheel and rear wheel travel on a same traveling path.

5. The conveyance system according to claim 2, wherein
one end of the traveling path is arranged on a side of the substrate processing apparatus on which a processing furnace is not provided, and the object is carried in and out from a front surface side of the substrate processing apparatus.

6. The conveyance system according to claim 2, wherein
the sub dolly includes guide rollers on both sides and travels on the traveling path provided with sidewalls on both sides.

7. The conveyance system according to claim 6, wherein
two guide rollers are provided on each side of the sub dolly at a height where the guide rollers are capable of contact with the sidewall of the traveling path, have a rotation shaft in a substantially vertical direction, and are configured to be rotatable in contact with the sidewall of the traveling path.

8. The conveyance system according to claim 3, further comprising:
a traveling path that is detachably provided in the substrate processing apparatus and includes a crank,
wherein
the sub dolly is configured to be movable in a left-right direction.

9. The conveyance system according to claim 8, wherein
at least one of the front wheel and the rear wheel of the sub dolly is a metal ball caster.

10. The conveyance system according to claim 1, wherein
the holder of the sub dolly includes a plate-shaped engager that can be fixed to a side surface of the object directly or with a bolt via a jig, and a lifting mechanism that raises or lowers the engager.

11. The conveyance system according to claim 1, wherein
the sub dolly includes a pair of auxiliary front wheels ahead the front wheels, and the auxiliary front wheels bear a load instead of the front wheels when the sub dolly is at a loading/unloading position of the object and a predetermined section immediately before the loading/unloading position of the object.

12. The conveyance system according to claim 11, wherein
the object is a substrate transfer robot used in a substrate processing apparatus, or is installed in an EFEM of the substrate processing apparatus.

13. The conveyance system according to claim 12, wherein
when the sub dolly is at the loading/unloading position of the object and the predetermined section immediately before the loading/unloading position of the object, the pair of auxiliary front wheels travels on auxiliary rails provided in the EFEM.

14. The conveyance system according to claim 12, further comprising:
a traveling path that is detachably provided in the substrate processing apparatus,
wherein
the traveling path is provided outside the EFEM.

15. The conveyance system according to claim 10, further comprising:
a traveling path that is detachably provided in the substrate processing apparatus,
wherein
the holder includes a support jig joined to the engager and grounded to the traveling path via wheels in a state of being at a height capable of engaging the object on which the engager is installed, and
the support jig is configured to be capable of directly transmitting at least a part of a load of the object to the traveling path.

16. A main dolly comprising:
a cargo platform;
three or more wheels that support the cargo platform; and
a handle that is connected to the cargo platform,
wherein
the main dolly is configured to be capable of carrying and conveying, on the cargo platform, a sub dolly including a front wheel and a rear wheel, a holder configured to hold an object so that its center of gravity is located ahead of the front wheel, and a counterweight detachably provided behind the front wheel, the sub dolly being in a state of holding the object.

17. A maintenance method for a semiconductor production apparatus comprising:
using a conveyance system including a main dolly that includes a cargo platform, three or more wheels supporting the cargo platform, and a handle connected to the cargo platform, and a sub dolly that is configured to be movable between a position on the cargo platform of the main dolly and a position outside the cargo platform, the sub dolly including a front wheel and a rear wheel enabling the sub dolly to move at least in a forward and backward direction, a holder configured to hold an object so that its center of gravity is located ahead of the front wheel, and a counterweight detachably provided behind the front wheel, the main dolly being configured to be capable of carrying and conveying the sub dolly in a state of holding the object, to cause the sub dolly to hold the object in the semiconductor production apparatus, carrying the sub dolly in a state of holding the object on the main dolly, and carrying out the sub dolly from the semiconductor production apparatus; and
carrying the sub dolly in a state of holding a replacement object on the main dolly and carrying the sub dolly into the semiconductor production apparatus, and disposing the replacement object held by the sub dolly inside the semiconductor production apparatus.

18. The maintenance method according to claim 17, further comprising:
directly transferring the object between the sub dolly mounted on the main dolly and a conveyance dolly; and
conveying the object with the conveyance dolly before or after the transferring.
